(19) United States
(12) Patent Application Publication
(10) Pub. No.: US 2018/0342630 A1
(43) Pub. Date: Nov. 29, 2018

(54) PEROVSKITE SOLAR BATTERY AND METHOD FOR PRODUCING SAME

(71) Applicants: Global Frontier Center for Multiscale Energy, Seoul (KR); Seoul National University R&DB Foundation, Seoul (KR)

(72) Inventors: Man Soo Choi, Seoul (KR); Heetae Yoon, Seoul (KR); Seong Min Kang, Seoul (KR); Namyoung Ahn, Seoul (KR); Jong-Kwon Lee, Seoul (KR)

(21) Appl. No.: 15/778,267

(22) PCT Filed: Jul. 18, 2016
(86) PCT No.: PCT/KR2016/007798

§ 371 Date: May 23, 2018

(30) Foreign Application Priority Data
Nov. 25, 2015 (KR) 10-2015-0165149

(51) Int. Cl. H01L 31/0216; H01L 31/0224; H01L 31/0392; H01L 31/04; H01L 31/18; H01L 51/44

(52) U.S. Cl. CPC H01L 31/02167; H01L 31/022425; H01L 51/441; H01L 31/04; H01L 31/18; H01L 31/0392

(57) ABSTRACT

A perovskite solar cell of the present invention has a structure in which an electron transport layer including a fullerene or a fullerene derivative is formed on a first electrode including a transparent conductive substrate and a blocking layer, such as a BCP layer, is absent, achieving improved electron transporting properties. The fullerene or fullerene derivative can perform a role as a blocking layer. Therefore, the use of the fullerene or fullerene derivative enables rapid fabrication of the solar cell with high efficiency.

### BACKGROUND OF THE INVENTION

### 1. Field of the Invention

The present invention relates to a perovskite solar cell and more specifically to a perovskite solar cell including an electron transport layer containing a fullerene or a fullerene derivative. The present invention also relates to a method for fabricating the perovskite solar cell.

### 2. Description of the Related Art

Conventional perovskite (CH₃NH₃PbI₃) materials for absorber layers of perovskite solar cells are formed into thin films by solution spin-coating processes, achieving high efficiency (≥15%). Thin perovskite absorber layers formed by simple spin coating processes known in the art have low homogeneity and quality, making it difficult to fabricate solar cells with ultra-high efficiency (≥19%). The fabrication of solar cells with ultra-high efficiency (≥19%) requires methods for producing highly dense and crystalline perovskite absorber layers with improved homogeneity and quality.

Since the report on the 9.7% solid-state perovskite solar cell employing MAPbI₃ (MA=CH₃NH₃) and spiro-MeOTAD, overcoming the dissolution problem of MAPbI₃ in liquid electrolyte, there is a surge in perovskite solar cell researches due to facile fabrication procedure and superb photovoltaic performance in both mesoscopic structure and planar structure. As a result, a power conversion efficiency (PCE) of 201.1% was certified by the U.S. National Renewable Energy Laboratory (NREL).

Conventional interface layers for perovskite solar cells are mostly deposited by solution processing techniques and some of them require high temperature sintering. However, the use of such layers is limited because high temperature sintering may cause damage to perovskite cells or may deteriorate the performance of perovskite cells.

Under these circumstances, perovskite solar cells with improved stability and low hysteresis are increasingly being investigated.

### SUMMARY OF THE INVENTION

The present invention is intended to provide a perovskite solar cell whose performance and efficiency exceed those of conventional perovskite solar cells and a method for fabricating the perovskite solar cell.

One aspect of the present invention provides a perovskite solar cell which includes a first electrode including a transparent conductive substrate, an electron transport layer formed directly on the first electrode and including a fullerene or fullerene derivative layer having a thickness of 20 nm or more, a perovskite layer formed directly on the electron transport layer, a hole transport layer formed on the perovskite layer, and a second electrode formed on the hole transport layer.

A further aspect of the present invention provides a method for fabricating the perovskite solar cell.

The perovskite solar cell of the present invention includes an electron transport layer containing a fullerene or a fullerene derivative and is free of a blocking layer, typified by a bathocuproine (BCP) layer. This structure allows the perovskite solar cell to have improved stability and low hysteresis. In addition, the present invention provides an optimal method for producing an electron transport layer containing a fullerene or a fullerene derivative.

### BRIEF DESCRIPTION OF THE DRAWINGS

FIG. 1 is a conceptual diagram showing potentials of the constituents of a solar cell including both BCP and C60 layers.

FIG. 2 shows series resistance (Rs) values of a solar cell including a C60 layer and a solar cell including a C70 layer.

FIG. 3 shows J-V curves showing hysteresis values of perovskite solar cells fabricated in Example 1 and Comparative Examples 1 and 2.

FIG. 4 shows changes in the Rs of solar cells including C60 layers formed at different deposition rates.

FIG. 5 shows (a) V_{oc} and (b) J_{sc} values of solar cells including C60 layers with different thicknesses.

FIG. 6 shows (c) PCE (%), (d) Rsc, and (e) Rs values of solar cells including C60 layers with different thicknesses.

FIG. 7 shows cross-sectional FIB-SEM images of perovskite solar cells including C60 layers deposited to different thicknesses of (a) 10 nm, (b) 20 nm, (c) 30 nm, (d) 35 nm, and (e) 40 nm.

### DETAILED DESCRIPTION OF THE INVENTION

The present invention will now be described in more detail.

The present invention provides a perovskite solar cell including a first electrode including a transparent conductive substrate, an electron transport layer formed directly on the first electrode and including a 20 nm-thick fullerene or fullerene derivative layer, a perovskite layer formed directly on the electron transport layer, a hole transport layer formed on the perovskite layer, and a second electrode formed on the hole transport layer.

The present invention also provides a method for fabricating the perovskite solar cell.

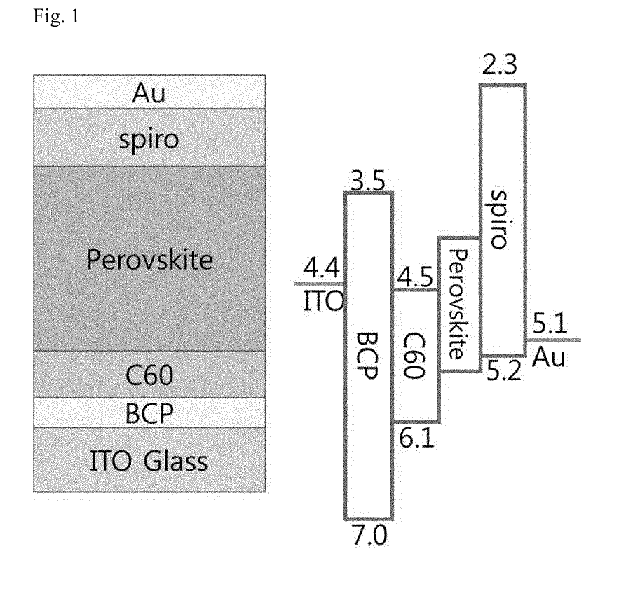

The perovskite solar cell of the present invention includes a fullerene or fullerene derivative layer as an electron transport layer and is free of a blocking layer, such as a bathocuproine (BCP) layer. FIG. 1 shows an energy band diagram of a perovskite solar cell using both C60 and BCP.

As shown in FIG. 1, BCP has a higher LUMO energy level than the perovskite, which makes it difficult for electrons generated from the perovskite to migrate to a transparent electrode. In contrast, the fullerene or its derivative as an electron transport layer has a lower LUMO energy level than the perovskite, which facilitates the migration of the electrons to the transparent electrode. Since the fullerene or its derivative has a lower HOMO energy level than the perovskite, holes generated from the perovskite can be blocked from migrating to a transparent electrode, and as a result, they can easily migrate to a metal electrode.

These effects may be different depending on the thickness of the electron transport layer. If the thickness of the electron transport layer is excessively small, the role of the electron transport layer in blocking the holes is not expected. Thus, the fullerene or fullerene derivative layer should be formed with a thickness above a predetermined level. Specifically, the fullerene or fullerene derivative layer should be deposited to a thickness exceeding 20 nm, for example, a thickness of 25 nm or above. If the fullerene or fullerene derivative layer has a thickness of about 20 nm or less, the efficiency of the solar cell may deteriorate. This small thickness facilitates migration of the electrons but is ineffective in blocking the holes, leading to low power conversion efficiency of the solar cell. Meanwhile, if the thickness of the fullerene or fullerene derivative layer is excessively large, internal resistance to the electron migration may be caused. Thus, the thickness of the fullerene or fullerene derivative layer is adjusted to about 100 nm or less, preferably 70 nm or less or 60 mm or less, more preferably 40 nm or less.

According to one embodiment of the present invention, the fullerene or fullerene derivative is selected from C60, C70, and derivatives thereof.

For example, fullerenes, such as phenyl-C61-butyric acid methyl ester (PCBM) and C60, may be used as materials for electron selective layers in perovskite solar cells. Solution-processed fullerenes are good passivation materials for CH₃NH₃PbI₃, can passivate grain boundaries, and reduce the density of trap states. In comparison with PCBM, C60 is inexpensive, has no long side chain, and can be densely stacked, which facilitates intermolecular electron transport. Solar cells having an inverted perovskite structure based on a solution-processed C60 interface layer exhibit much better performance than solar cells based on PCBM and indene-C60 bisadduct interface layers. For these reasons, C60 is a very suitable material for electron transport layers of perovskite solar cells.

The absence of a BCP layer in the solar cell of the present invention ensures improved electron mobility, which brings about an improvement in electrical properties, such as J_{sc} and V_{oc}. Particularly, the solar cell of the present invention exhibits high J_{sc}, indicating its good ability to absorb light and eventually resulting in high power conversion efficiency. For example, the solar cell of the present invention may exhibit a current density (J_{sc}) of at least 20 mA/cm² due to its structure. Preferably, the solar cell of the present invention exhibits a J_{sc} of at least 22 mA/cm². In addition, the solar cell of the present invention exhibits a power conversion efficiency as high as at least 16%, preferably at least 16.5%, more preferably at least 17%.

According to one embodiment, electrons and holes migrate sufficiently in the solar cell of the present invention, making the solar cell nearly free of hysteresis. For example, the solar cell of the present invention has a hysteresis of 5% or less, 2% or less or 1% or less. The hysteresis of the solar cell is preferably 0.5% or less, more preferably 0.4% or less.

According to one embodiment, the solar cell of the present invention may have a resistance at J_{sc} (Rsc) of about 8,000 ohms or more, preferably 8,500 ohms or more, more preferably 9,000 ohms or more or 10,000 ohms or more.

According to one embodiment, the solar cell of the present invention may have a series resistance (Rs) of about 200 ohms or less, preferably 150 ohms or less, more preferably 100 ohms or less. The Rs is indicative of interface resistance between the constituent layers and the presence of defects in the device. A lower Rs may be a more favorable condition for the migration of electrons between layers, achieving higher power conversion efficiency.

The solar cell of the present invention may use a perovskite represented by Formula 1:

APbX₃ (1)

wherein A is an organic cation, an inorganic cation or a combination thereof and each X is independently F⁻, Cl⁻, Br⁻ or I⁻ as a halogen ion.

According to one embodiment, the composition of the cation and the halogen anions in the perovskite may be changed and the crystal structure of the perovskite may be cubic.

Due to its cubic structure, the perovskite of the present invention can maintain its more stable phase under illumination conditions, ensuring very high stability against exposure to light. Meanwhile, the crystal structure of a perovskite having a non-cubic crystal structure (for example, a tetragonal structure) may become unstable when exposed to light. For example, the perovskite may undergo a phase transition, losing its structural stability. The difference in stability between a cubic perovskite structure and a tetragonal perovskite structure may increase over time.

According to one embodiment, A in Formula 1 may be an organic cation represented by Formula 2:

(R₁R₂N═CH—NR₃R₄)+ (2)

wherein R₁, R₂, R₃, and R₄ are each independently selected from hydrogen and substituted or unsubstituted C1-C6 alkyl,

an organic cation represented by Formula 3:

(R₅R₆R₇R₈N)⁺ (3)

wherein R₅, R₆, R₇, and Rs are each independently hydrogen, substituted or unsubstituted C₁-C₂₀ alkyl or substituted or unsubstituted aryl, a Cs⁺ cation, or a combination thereof.

More specifically, A in Formula 1 may be selected from CH₃NH₃⁺ (methylammonium, MA), CH(NH₂)₂⁺ (formamidinium, FA), Cs⁺, and combinations thereof.

The perovskite of the present invention includes a mixed structure in which A consists of two or more cations and X consists of two or more anions. In this mixed structure, the skeleton of the perovskite may be modified by varying the individual anions. According to the present invention, the anions allow the perovskite to have a cubic structure. That is, the presence of the anions facilitates control over the characteristics of the perovskite and leads to an improvement in the performance of the photoelectronic device including the perovskite.

The alteration of the organic cation (or organic cations) present in the perovskite can usually affect the structural and/or physical properties of the perovskite. The electronic properties and optical properties of the material can be controlled by varying the organic cation used, which is particularly useful in controlling the characteristics of the photoelectronic device including the perovskite. For example, the conductivity of the material may be increased or decreased by varying the organic cation. Further, when the organic cation varies, the band structure of the material may be modified, for example, so that the bandgap of the semiconductor material can be controlled.

The present invention also provides an adduct compound as a precursor for the preparation of the perovskite, represented by Formula 4:

AX′.PbY₂.Q (4)

wherein A is an organic or inorganic cation, X⁻ is F⁻, Cl⁻, Br⁻ or I⁻ as a halogen ion, each Y is independently F⁻, Cl⁻, Br⁻ or I⁻ as a halogen ion, and Q is a Lewis base including a functional group containing an atom with an unshared pair of electrons as an electron pair donor.

A in Formula 4 is as defined in Formula 1.

The atom with an unshared pair of electrons is a nitrogen (N), oxygen (O) or sulfur (S) atom and the FT-IR peak of the functional group in the compound of Formula 4 is red-shifted by 1 to 10 cm⁻¹ relative to that in a compound represented by Formula 5:

PbY₂.Q (5)

wherein Y and Q are as defined in Formula 4.

The present invention also provides a method for preparing the adduct compound.

The present invention also provides a perovskite prepared using the adduct compound.

Q in Formula 4 is a Lewis base including a functional group containing a nitrogen (N), oxygen (O) or sulfur (S) atom as an electron pair donor. Specifically, Q in Formula 4 may be a Lewis base including at least one functional group selected from the group consisting of thioamide, thiocyanate, thioether, thioketone, thiol, thiophene, thiourea, thiosulfate, thioacetamide, carbonyl, aldehyde, carboxyl, ether, ester, sulfonyl, sulfo, sulfinyl, thiocyanato, pyrrolidinone, peroxy, amide, amine, imide, imine, azide, pyridine, pyrrole, nitro, nitroso, cyano, nitroxy, and isocyano groups, each of which has a nitrogen, oxygen or sulfur atom as an electron pair donor. A compound including at least one functional group selected from the group consisting of thioamide, thiocyanate, thioether, thioketone, thiol, thiophene, thiourea, thioacetamide, and thiosulfate groups, each of which has a sulfur (S) atom as an electron pair donor, is more preferred because of its ability to form a strong bond with the lead halide.

More specifically, Q in Formula 4 may be selected from the group consisting of dimethyl sulfoxide (DMSO), N,N-dimethylacetamide (DMA), N-methyl-2-pyrrolidinone (MPLD), N-methyl-2-pyridine (MPD), 2,6-dimethyl-γ-pyrone (DMP), acetamide, urea, thiourea (TU), N,N-dimethylthioacetamide (DMTA), thioacetamide (TAM), ethylenediamine (EN), tetramethylethylenediamine (TMEN), 2,2′-bipyridine (BIPY), 1,10-piperidine, aniline, pyrrolidine, diethylamine, N-methylpyrrolidine, n-propylamine, and combinations thereof. Preferably, Q in Formula 4 is selected from thiourea (TU), N,N-dimethylthioacetamide (DMTA), and thioacetamide (TAM), each of which includes a sulfur (S) atom as an electron pair donor.

According to the present invention, the FT-IR peak corresponding to the functional group containing the electron pair donor atom where the Lewis base represented by Q is bonded to Pb is red-shifted by 10 to 30 cm⁻¹ relative to that in the compound of Formula 5. This red shift is explained by the formation of the adduct from the bonding of the Pb metal atom to the Lewis base. That is, this adduct formation weakens the bonding strength of the functional group containing the electron pair donor of the Lewis base. This leads to strong bonding of the Lewis base to Pb, affecting the bonding strength of the electron pair donating functional group. This result is because the lead halide acts as a Lewis acid to form the adduct via Lewis acid-base reaction with the Lewis base. Specifically, the lead halide and the Lewis base share the unpaired electron in the Lewis base to form a bond, which further stabilizes the phase of the lead halide adduct.

The Lewis base may be in the form of a liquid and is preferably non-volatile or only slightly volatile. The Lewis base may have a boiling point of 120° C. or above, for example 150° C. or above.

According to the present invention, the method for preparing the lead halide adduct of Formula 4 includes: dissolving a lead halide, an organic or inorganic halide, and a Lewis base including a nitrogen (N), oxygen (O) or sulfur (S) atom as an electron pair donor in a first solvent to prepare a precursor solution; and adding a second solvent to the precursor solution to collect the resulting precipitate by filtration.

The lead halide, the halide including a divalent cation, and the organic material including a ligand may be mixed in a molar ratio of 1:1:1-1.5, most preferably 1:1:1.

According to one embodiment, the first solvent may be an organic solvent that can dissolve the lead halide, the organic or inorganic halide, and the organic material including a functional group containing a nitrogen (N), oxygen (O) or sulfur (S) atom as an electron pair donor, and may be selected from the group consisting of propanediol-1,2-carbonate (PDC), ethylene carbonate (EC), diethylene glycol, propylene carbonate (PC), hexamethylphosphoric triamide (HMPA), ethyl acetate, nitrobenzene, formamide, γ-butyrolactone (GBL), benzyl alcohol, N-methyl-2-pyrrolidone (NMP), acetophenone, ethylene glycol, trifluorophosphate, benzonitrile (BN), valeronitrile (VN), acetonitrile (AN), 3-methoxypropionitrile (MPN), dimethyl sulfoxide (DMSO), dimethyl sulfate, aniline, N-methylformamide (NMF), phenol, 1,2-dichlorobenzene, tri-n-butyl phosphate, o-dichlorobenzene, selenium oxychloride, ethylene sulfate, benzenethiol, dimethylacetamide, diethylacetamide, N,N-dimethylethanamide (DMEA), 3-methoxypropionitrile (MPN), diglyme, cyclohexanol, bromobenzene, cyclohexanone, anisole, diethylformamide (DEF), dimethylformamide (DMF), 1-hexanethiol, hydrogen peroxide, bromoform, ethyl chloroacetate, 1-dodecanethiol, di-n-butyl ether, dibutyl ether, acetic anhydride, m-xylene, p-xylene, chlorobenzene, morpholine, diisopropyl ethylamine, diethyl carbonate (DEC), 1-pentanediol, n-butyl acetate, 1-hexadecanethiol, and mixtures thereof.

The first solvent may be added in an excessive amount. Preferably, the first solvent is added in such an amount that the weight ratio of the lead halide to the first solvent is 1:1-3.

According to one embodiment, the second solvent may be a nonpolar or weakly polar solvent that is capable of selectively removing the first solvent. For example, the second solvent may be selected from the group consisting of acetone-based solvents, C₁-C₃ alcohol-based solvents, ethyl acetate-based solvents, diethyl ether-based solvents, alkylene chloride-based solvents, cyclic ether-based solvents, and mixtures thereof.

According to one embodiment, the use of toluene and chlorobenzene as general volatile solvents for the preparation of the perovskite from the lead halide adduct may lead to low reproducibility because the quality of the perovskite is significantly dependent on dripping amount and/or spinning rate of washing solution and the difference in solubility between the solvent for washing and the solvent in the precursor solution. In contrast, high reproducibility of the perovskite film can be obtained using the second solvent, preferably a diethyl ether-based solvent, regardless of spin coating condition if enough amount of the second solvent is used for dissolving the first solvent completely.

The combined use of the first and second solvents for the preparation of the lead halide adduct allows the product to have a denser structure because the use of the volatile second solvent enables removal of the first solvent, ensuring rapid and uniform crystallization.

According to one embodiment, the lead halide adduct may form a transparent thin film. The lead halide adduct in the form of a thin film may be heated to a temperature of 30° C. or above, preferably 40° C. or above or 50° C. or above. For example, the lead halide adduct may be heated to the temperature range of 30° C. to 150° C. to form the desired perovskite. The heating may be performed at a temperature of 30° C. to 80° C. and subsequently at a temperature of 90° C. to 150° C. The additional heating allows the perovskite crystal to have a dense structure. The annealing process enables the removal of the organic ligand corresponding to Q in Formula 4 from the crystal structure of the lead halide adduct, leading to the formation of the perovskite. According to one embodiment, the resulting perovskite thin film may have a dark color, such as dark brown.

The perovskite of the present invention is highly stable under illumination conditions. Due to this advantage, the perovskite thin film absorbs an increased amount of light and permits electrons and holes to rapidly migrate therethrough. Therefore, the use of the perovskite thin film enables the fabrication of a high-efficiency solar cell.

According to one embodiment, the lead halide adduct is formed into a thin film on the first electrode including a transparent substrate by a spin-coating process. The transparent substrate may be made of a transparent conductive oxide layer. As the transparent conductive oxide, there may be used, for example, fluorine doped tin oxide (FTO), indium tin oxide (ITO), indium zinc oxide (IZO), indium zinc tin oxide (IZTO), aluminum zinc oxide (AZO), indium tin oxide-silver-indium tin oxide (ITO—Ag—ITO), indium zinc oxide-silver-indium zinc oxide (IZO—Ag—IZO), indium zinc tin oxide-silver-indium zinc tin oxide (IZTO—Ag—IZTO), aluminum zinc oxide-silver-aluminum zinc oxide (AZO—Ag-AZO), aluminum oxide (Al₂O₃), zinc oxide (ZnO), magnesium oxide (MgO) or graphene. Particularly, indium tin oxide (ITO) or graphene is preferably used. The use of ITO with a more uniform surface is preferred because the film can be formed more homogeneously with the desired thickness.

In the perovskite cell of the present invention, the fullerene or a fullerene derivative electron transport layer is formed on the transparent electrode without forming a blocking layer, such as a BCP layer, therebetween. The use of the fullerene or fullerene derivative allows the perovskite cell to have high electron mobility.

According to the present invention, the electron transport layer may be formed on the transparent electrode by using a thermal evaporator at a constant evaporation rate. More specifically, the electron transport layer can be formed by deposition of a fullerene at a constant evaporation rate in an ultra-high vacuum of up to 10⁻⁷ Pa.

According to the present invention, the rate at which the fullerene is deposited may have an influence on the structure of the fullerene layer, affecting the resistance properties (such as Rs) of the cell. Particularly, a high deposition rate may deteriorate the homogeneity of the fullerene layer, resulting in an increase in the interface resistance between the transparent electrode and the perovskite. Thus, the Rs resistance tends to increase in proportion to the deposition rate. From this tendency, it is possible to obtain an appropriate range of the deposition rate within which the morphology of the fullerene layer is not affected. The optimal deposition rate allows for rapid fabrication of the solar cell with high efficiency. According to a preferred embodiment of the present invention, the deposition rate is from about 0.01 Å/s to about 0.15 Å/s or about from 0.02 Å/s to about 0.1 Å/s. The deposition rate is preferably from about 0.03 Å/s to about 0.08 Å/s or from about 0.04 to about 0.1 Å/s.

The second electrode may be made of at least one metal selected from the group consisting of Pt, Au, Ni, Cu, Ag, In, Ru, Pd, Rh, Ir, Os, C, and combinations thereof.

The method for preparing the lead halide adduct and the solar cell including the perovskite prepared by the method will be more specifically explained with reference to the following examples, including experimental examples. However, these examples are merely illustrative and should not be construed as limiting the scope of the invention.

### Example 1: Fabrication of Perovskite Solar Cell Including C60

An ITO glass substrate (AMG, 9.5 Ωcm⁻², 25×25 mm²) was cleaned with isopropyl alcohol, acetone, and deionized water (each for 20 min) in an ultrasonic bath and stored in an oven at 120° C. before use. C60 was deposited by using thermal evaporator at an evaporation rate of 0.05 Å/s to form a C60 electron transport layer having a final thickness of 35 nm.

461 mg of PbI₂, 159 mg of MAI, and 78 mg of DMSO (molar ratio 1:1:1) were mixed in 600 mg of DMF at room temperature with stirring for 1 h in order to prepare a MAI.PbIz.DMSO adduct solution. The completely dissolved solution was spin-coated on the C60 layer at 4000 rpm for 25 sec and 0.5 ml of diethyl ether (DE) was slowly dripped on a rotating substrate in 10 sec before the surface changed to be turbid caused by rapid vaporization of DMF. The resulting transparent MAI.PbI₂.DMSO adduct film was heated at 65° C. for 1 min. The subsequent heating at 100° C. for 2 min allowed a dark-brown MAPbI₃ film having a dense structure.

20 μl of a spiro-MeOTAD solution was spin-coated on the perovskite layer at 3000 rpm for 3 sec. The spiro-MeOTAD solution was composed of 72.3 mg spiro-MeOTAD (Merck), 28.8 μl of 4-tert-butylpyridine, and 17.5 μl of a lithium bis(trifluoromethanesulfonyl)imide (Li-TFSI) solution (520 mg Li-TSFI in 1 ml acetonitrile (Sigma-Aldrich, 99.8%)) in 1 ml of chlorobenzene.

Finally, Au electrode was deposited by using thermal evaporator at a constant evaporation rate.

### Example 2: Fabrication of Perovskite Solar Cell Including C70

A perovskite solar cell was fabricated in the same manner as in Example 1, except that C70 was used instead of C60.

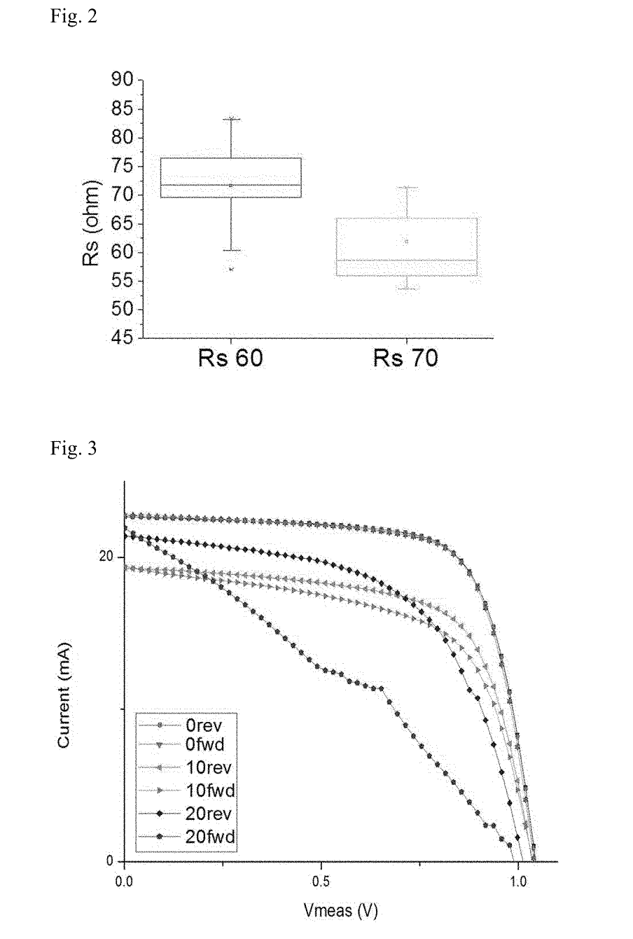

The Rs values of the solar cells fabricated in Examples 1-2 were measured. The results are shown in FIG. 2.

### Comparative Example 1: Fabrication of Solar Cell Including BCP (10 nm) and C60

An ITO glass substrate (AMG, 9.5 Ωcm⁻², 25×25 mm²) was cleaned with isopropyl alcohol, acetone, and deionized water (each for 20 min) in an ultrasonic bath and stored in an oven at 120° C. before use. UVO was treated for 30 min prior to use. A 10 nm-thick blocking layer including BCP was formed on the ITO electrode. C60 was deposited by using thermal evaporator at an evaporation rate of 0.05 Ais to form a C60 electron transport layer having a final thickness of 35 nm. The subsequent procedure was the same as that described in Example 1.

### Comparative Example 2: Fabrication of Perovskite Solar Cell Including BCP (20 nm) and C60

An ITO glass substrate (AMG, 9.5 Ωcm⁻², 25×25 mm²) was cleaned with isopropyl alcohol, acetone, and deionized water (each for 20 min) in an ultrasonic bath and stored in an oven at 120° C. before use. UVO was treated for 30 min prior to use. A 20 nm-thick blocking layer including BCP was formed on the ITO electrode. C60 was deposited by using thermal evaporator at a constant evaporation rate to form a C60 electron transport layer having a final thickness of 35 nm. The subsequent procedure was the same as that described in Example 1.

### Experimental Example 1: Evaluation of Hysteresis of the Solar Cells

A scan direction test was conducted to evaluate the J-V hysteresis of the solar cells fabricated in Example 1 and Comparative Examples 1-2. The measured current density-voltage curves are shown in FIG. 3. Table 1 describes the values measured in the scan direction test on the solar cells of Example 1 and Comparative Examples 1-2.

TABLE 1

| | | V_{oc} | J_{sc} | | PCE | | | Power | Hysteresis |
|---|---|---|---|---|---|---|---|---|---|
| Device # | | (V) | (mA/cm²) | FF | (%) | R @ V_{oc} | R @ I_{sc} | (W) | (%) |
| Example 1 | Fwd | 1.04 | 22.79 | 71.35 | 16.90 | 56.41 | 8913.28 | 0.0019 | 0.26 |
| | Rev | 1.04 | 22.66 | 71.72 | 16.95 | 52.04 | 13049.19 | 0.0019 | |
| Comparative | Fwd | 1.04 | 19.52 | 60.35 | 12.20 | 77.42 | 2433.99 | 0.0015 | 8.60 |
| Example 1 | Rev | 1.03 | 19.27 | 66.97 | 13.35 | 72.19 | 8456.13 | 0.0016 | |
| Comparative | Fwd | 0.98 | 21.97 | 35.14 | 7.56 | 226.28 | 656.73 | 0.0011 | 39.06 |
| Example 2 | Rev | 1.01 | 21.40 | 57.30 | 12.40 | 94.63 | 4005.60 | 0.0016 | |

As can be seen from the results in Table 1, the solar cell of Example 1 showed better results in terms of current density and open-circuit voltage than the solar cell of Comparative Example 2, demonstrating a higher fill factor (%) of the former than that of the latter. In addition, the solar cell of Example 1 showed a significantly higher power conversion efficiency than the solar cells including BCP.

In the J-V curve of the BCP-free solar cell of Example 1, no substantial hysteresis was found between the forward (V_{oc} at J_{sc}) and reverse directions (J_{sc} at V_{oc}) during the current-voltage measurement. In contrast, a significantly larger hysteresis was observed in the solar cell of Comparative Example 1. Particularly, a very large hysteresis was observed in the solar cell of Comparative Example 2.

C60 has the ability to transport electrons and block holes, as shown in FIG. 1. Despite the ability of C60, the formation of the BCP blocking layer can impede the migration of electrons supplied from the photoactive layer. This affects the performance of the cell, causing the occurrence of hysteresis. In contrast, since C60 has a potential range within which electrons can be transported and holes can be blocked, the C60 layer can act as both an electron transport layer and a blocking layer, eliminating the need for a blocking layer. Therefore, the formation of the C60 layer can reduce interface resistance and the number of processing steps, enabling the fabrication of the perovskite solar cell with higher efficiency.

### Example 3: Fabrication of Solar Cell Including C60 Deposited at Rate of 0.05 Å/s

A solar cell was fabricated in the same manner as in Example 1, except that C60 was deposited at a rate of 0.05 Å/s.

### Example 4: Fabrication of Solar Cell Including C60 Deposited at Rate of 0.1 Å/s

A solar cell was fabricated in the same manner as in Example 1, except that C60 was deposited at a rate of 0.1 Å/s.

### Example 5: Fabrication of Solar Cell Including C60 Deposited at Rate of 0.8 Å/s

A solar cell was fabricated in the same manner as in Example 1, except that C60 was deposited at a rate of 0.8 Å/s.

### Experimental Example 2: Comparison of Performance Characteristics of the Solar Cells Including C60 Deposited at Different Rates

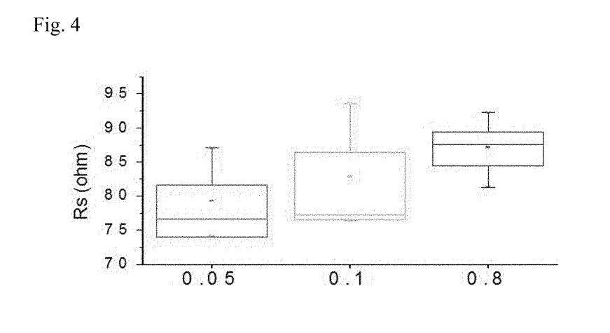

The Rs values of the solar cells fabricated in Examples 3-5 were measured. The results are shown in FIG. 4.

As shown in FIG. 4, the Rs tended to increase with increasing deposition rate, suggesting the possibility of structural defects, such as heterogeneity of C60, in the film with increasing deposition rate. Based on these results, it is possible to obtain an appropriate range of the deposition rate within which C60 can be deposited more rapidly without affecting the characteristics of the cells.

### Comparative Example 3: Fabrication of Solar Cell Including C60 Deposited to Thickness of 0.8 Å/s

A solar cell was fabricated in the same manner as in Example 1, except that C60 was deposited to a thickness of 10 nm at a rate of 0.05 Å/s.

### Example 6: Fabrication of Solar Cell Including C60 Deposited to Thickness of 20 nm

A solar cell was fabricated in the same manner as in Example 1, except that C60 was deposited to a thickness of 20 nm at a rate of 0.05 Å/s.

### Example 7: Fabrication of Solar Cell Including C60 Deposited to Thickness of 30 nm

A solar cell was fabricated in the same manner as in Example 1, except that C60 was deposited to a thickness of 30 nm at a rate of 0.05 Å/s.

### Example 8: Fabrication of Solar Cell Including C60 Deposited to Thickness of 35 nm

A solar cell was fabricated in the same manner as in Example 1, except that C60 was deposited to a thickness of 35 nm at a rate of 0.05 Å/s.

### Example 9: Fabrication of Solar Cell Including C60 Deposited to Thickness of 40 nm

A solar cell was fabricated in the same manner as in Example 1, except that C60 was deposited to a thickness of 40 nm at a rate of 0.05 Å/s.

### Experimental Example 3: Comparison of Performance Characteristics of the Solar Cells Including the C60 Layers Formed with Different Thicknesses

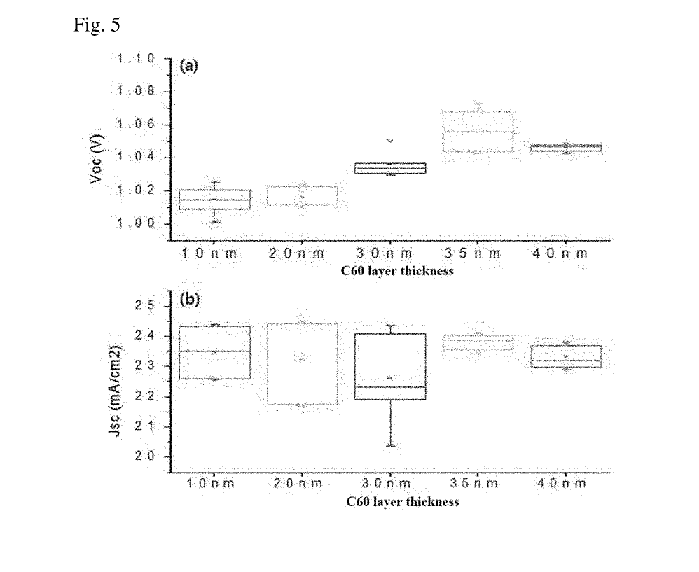

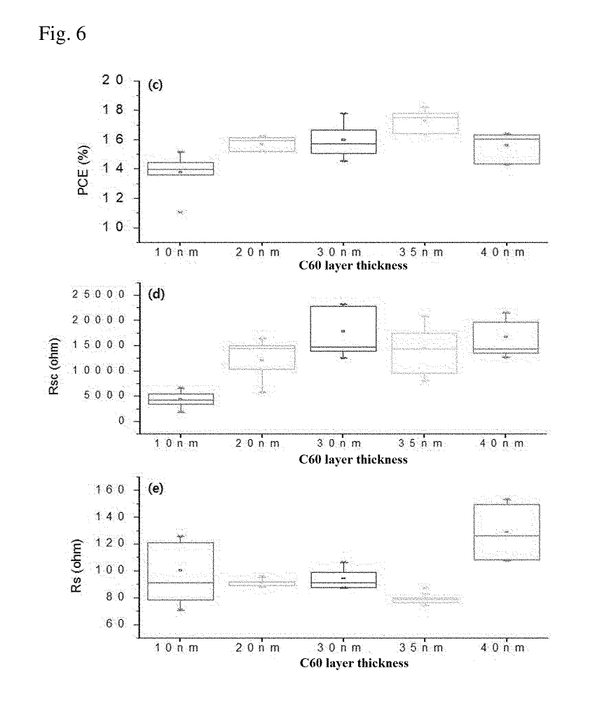

FIG. 5 shows (a) open-circuit voltage (V_{oc}) and (b) short-circuit current (J_{sc}) values of the solar cells fabricated in Comparative Example 3 and Examples 6-9. FIG. 6 shows (c) power conversion efficiency (PCE, %), (d) Rsc (R at Isc), and (e) series resistance (Rs) values of the solar cells.

From the results in FIGS. 5 and 6, it can be seen that the deposition of C60 to thicknesses of ≥10 nm was effective in improving the electrical properties, such as efficiency, J_{sc}, and V_{oc}, of the solar cells. Particularly, it was demonstrated based on the Rs values that the cell including the <15 nm-thick C60 layer was defective, probably because the C60 film was incompletely formed. Further, the cell including the <20 nm-thick C60 layer had a considerably low Rsc, resulting in low power conversion efficiency (<15%).

Based on the above results, it is possible to obtain an appropriate range of the C60 layer thickness within which optimal electron transport properties and blocking effects can be elicited. Specifically, the electron transport properties and blocking effects of C60 can be optimized when the C60 layer thickness is larger than 20 nm, for example, in the range of about 20-60 nm, preferably about 25 nm-50 nm, more preferably about 25 nm-40 nm.

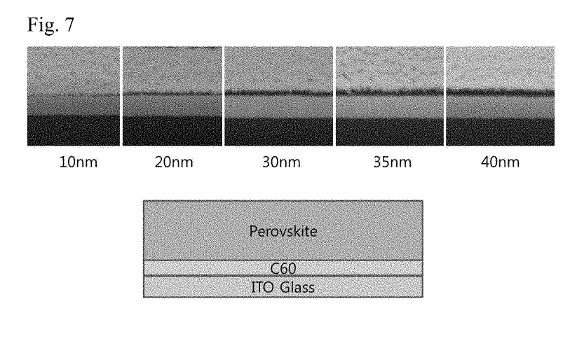

FIG. 7 shows cross-sectional images of the cells including the C60 layers deposited to different thicknesses. The 10 nm-thick C60 layer cannot act as both a blocking layer and a transport layer due to its too small thickness.

While specific embodiments of the invention have been described in detail, it will be appreciated by those skilled in the art that such detailed descriptions are merely preferred embodiments and the scope of the present invention is not limited thereto. Therefore, the true scope of the present invention should be defined by the appended claims and their equivalents.

1. A perovskite solar cell comprising: a first electrode comprising a transparent conductive substrate; an electron transport layer formed directly on the first electrode and comprising a fullerene or fullerene derivative layer having a thickness of 20 nm or more; a perovskite layer formed directly on the electron transport layer; a hole transport layer formed on the perovskite layer; and a second electrode formed on the hole transport layer.

2. The perovskite solar cell according to claim 1, wherein the electron transport layer comprises at least one material selected from C60, C70, and derivatives thereof.

3. The perovskite solar cell according to claim 1, wherein the electron transport layer has a thickness of 100 nm or less.

4. The perovskite solar cell according to claim 1, wherein the electron transport layer has a thickness of 20 to 60 nm.

5. The perovskite solar cell according to claim 1, wherein the solar cell has a hysteresis of 5% or less.

6. The perovskite solar cell according to claim 1, wherein the solar cell has a power conversion efficiency of at least 16%.

7. The perovskite solar cell according to claim 1, wherein the transparent conductive substrate is made of indium tin oxide (ITO) or graphene.

8. The perovskite solar cell according to claim 1, wherein the solar cell has a series resistance (Rs) of 200 ohms or less.

9. A method for fabricating the perovskite solar cell according to claim 1, the method comprising depositing a fullerene or a fullerene derivative to a thickness of 20 nm or more on a first electrode comprising a transparent conductive substrate to form an electron transport layer, forming a perovskite layer on the electron transport layer, forming a hole transport layer on the perovskite layer, and forming a second electrode on the hole transport layer.

10. The method according to claim 9, wherein the fullerene or fullerene derivative is deposited on the first electrode by thermal evaporation.

11. The method according to claim 9, wherein the electron transport layer is formed by deposition of the fullerene or fullerene derivative on the first electrode comprising a transparent conductive substrate at a controlled rate of 2.0 nm/s or less.

12. The method according to claim 9, wherein the electron transport layer is formed by deposition of the fullerene or fullerene derivative on the first electrode comprising a transparent conductive substrate at a controlled rate of 0.01 to 0.15 Å/s.

13. The perovskite solar cell according to claim 1, wherein the perovskite is represented by Formula 1:
APbX₃ (1)
wherein A is an organic or inorganic cation and X is F⁻, Cl⁻, Br⁻ or I⁻ as a halogen ion.

14. The perovskite solar cell according to claim 13, wherein A in Formula 1 is selected from an organic cation represented by Formula 2:
(R₁R₂N═CH—NR₃R₄)⁺ (2)
wherein R₁, R₂, R₃, and R₄ are each independently selected from hydrogen and substituted or unsubstituted C₁-C₆ alkyl,
an organic cation represented by Formula 3:
(R₅R₆R₇R₈N)⁺ (3)
wherein R₅, R₆, R₇, and R₈ are each independently hydrogen, substituted or unsubstituted C₁-C₂₀ alkyl or substituted or unsubstituted aryl, a Cs⁺ cation, and combinations thereof.

15. The perovskite solar cell according to claim 13, wherein A in Formula 1 is selected from CH₃NH₃⁺, CH(NH₂)₂⁺, Cs⁺, and combinations thereof.

16. The perovskite solar cell according to claim 13, wherein the perovskite comprises a mixed structure in which A consists of two or more cations and X consists of two or more halogen anions.

17. The perovskite solar cell according to claim 13, wherein the perovskite is prepared from an adduct compound represented by Formula 4:
AX′.PbY₂.Q (4)
wherein A is an organic or inorganic cation, X′ and Y are each independently F⁻, Cl⁻, Br⁻ or I⁻ as a halogen ion, and Q is a Lewis base comprising a functional group containing an atom with an unshared pair of electrons as an electron pair donor.
